(19) United States
(12) Patent Application Publication
(10) Pub. No.: US 2020/0341590 A1
(43) Pub. Date: Oct. 29, 2020

(54) DISPLAY PANEL AND DISPLAY DEVICE

(71) Applicants: Wenqi LI, Wuhan (CN); Caigin CHEN, Wuhan (CN)

(72) Inventors: Wenqi LI, Wuhan (CN); Caigin CHEN, Wuhan (CN)

(21) Appl. No.: 16/611,484

(22) PCT Filed: Jun. 17, 2019
(86) PCT No.: PCT/CN2019/091481

§ 371 Date: Nov. 7, 2019

(30) Foreign Application Priority Data
Apr. 23, 2019 (CN) 201910327870.2

(51) Int. Cl. G06F 3/044; G06F 3/041; H01L 51/52; H01L 27/32

(52) U.S. Cl. CPC G06F 3/0445; G06F 3/0412; G06F 2203/04103; H01L 27/323; H01L 27/3244; H01L 51/5228

(57) ABSTRACT

The present application provides a display panel and a display device. The display panel includes a cathode layer formed by a low-temperature process, and a first gap is disposed on the cathode layer. In the present application, generated lines of force are not shielded by the cathode layer because the first gap is disposed on the cathode layer. After a finger touches screen, the generated lines of force can penetrate a structure under the cathode layer. The cathode layer is formed by the low-temperature process, thereby avoiding damage to luminescent material.

### FIELD OF INVENTION

The present application relates to the field of display, and in particular, to a display panel and a display device.

### BACKGROUND OF INVENTION

In an active-matrix organic light-emitting diode (AMOLED) display panel structure, current touch control structure is implemented by on-cell technology. That is, all touch function layer is attached to a cathode layer of the uppermost layer of the organic light-emitting diode (OLED), away from a back panel. This is because the cathode layer is prepared by a common mask evaporation process, such that the structure is unitary planar. After a finger touches the screen, generated lines of force are shielded by the cathode layer and cannot penetrate the structure under the cathode layer.

### Technical Problem

That is, the current display panel has a technical problem that the touch control structure can only be implemented by on-cell technology.

### SUMMARY OF INVENTION

The present application provides a display panel and a display device to solve the technical problem that the touch control structure of the current display panel can only be implemented by on-cell method.

To solve the above problem, the present application provides a technical solution described below.

One embodiment of the present application provides a display panel, including: a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

In a display panel of the present application, the display panel includes a pixel defining layer, and the pixel defining layer is provided with a support retaining wall thereon; wherein a height of the supporting retaining wall is greater than a thickness of the cathode layer; and wherein the cathode layer is divided to form the first gap.

In a display panel provided by one embodiment of the present application, the support retaining wall has a triangular cross-section.

In a display panel provided by one embodiment of the present application, the support retaining wall has a trapezoidal cross-section.

In a display panel provided by one embodiment of the present application, the support retaining wall has an inverted trapezoidal cross-section.

In a display panel provided by one embodiment of the present application, the cathode layer includes a first region and a second region, and the first gap is disposed between the first region and the second region, and wherein the cathode layer of the first region and the second region is formed by a plurality of processes.

In a display panel provided by one embodiment of the present application, the touch function layer is the same layer as the cathode layer, and wherein the cathode layer of the first region forms a first touch electrode, and the cathode layer of the second region forms a second touch electrode.

In a display panel provided by one embodiment of the present application, the first touch electrode is a driving electrode, and the second touch electrode is a sensing electrode; or the first touch electrode is a sensing electrode, and the second touch electrode is a driving electrode.

In a display panel provided by one embodiment of the present application, the display panel includes a passivation layer and a protective layer sequentially disposed on the cathode layer, and the first gap is formed by etching the passivation layer, the protection layer, and the cathode layer in one process.

In a display panel provided by one embodiment of the present application, the first gap is formed by stripping a stripping layer disposed under the cathode layer.

One embodiment of the present application provides a display panel, including: a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

One embodiment of the present application provides a display panel, including: a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

In a display device provided by one embodiment of the present application, the display panel includes a pixel defining layer, and the pixel defining layer is provided with a support retaining wall thereon; wherein a height of the supporting retaining wall is greater than a thickness of the cathode layer; and wherein the cathode layer is divided to form the first gap.

In a display device provided by one embodiment of the present application, the support retaining wall has a triangular cross-section.

In a display device provided by one embodiment of the present application, the support retaining wall has a trapezoidal cross-section.

In a display device provided by one embodiment of the present application, the support retaining wall has an inverted trapezoidal cross-section.

In a display device provided by one embodiment of the present application, the cathode layer includes a first region and a second region, and the first gap is disposed between the first region and the second region, and wherein the cathode layer of the first region and the second region is formed by a plurality of processes.

In a display device provided by one embodiment of the present application, the touch function layer is the same layer as the cathode layer, and wherein the cathode layer of the first region forms a first touch electrode, and the cathode layer of the second region forms a second touch electrode.

In a display device provided by one embodiment of the present application, the first touch electrode is a driving electrode, and the second touch electrode is a sensing electrode; or the first touch electrode is a sensing electrode, and the second touch electrode is a driving electrode.

In a display device provided by one embodiment of the present application, the display panel includes a passivation layer and a protective layer sequentially disposed on the cathode layer, and the first gap is formed by etching the passivation layer, the protection layer, and the cathode layer in one process.

In a display device provided by the embodiment of the present application, the first gap is formed by stripping a stripping layer disposed under the cathode layer.

### Beneficial Effect

The display panel includes a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

In this structure, based on the first gap formed on the cathode layer, after a finger touches screen, the generated lines of force are not shielded by the cathode layer and can penetrate a structure under the cathode layer. In this way, at least part of the touch function layer can be not disposed on the cathode layer of the uppermost layer of the OLED away from the back panel, thereby solving the technical problem that the current display panel can only adopt the on-cell method. In addition, the cathode layer is formed by low-temperature process, which avoids damage to the luminescent material.

### DESCRIPTION OF DRAWINGS

In order to more clearly illustrate the technical solutions in the embodiments of the present invention, the following figures described in the embodiments will be briefly introduced. It is obvious that the drawings described below are merely some embodiments of the present invention, other drawings can also be obtained by the person ordinary skilled in the field based on these drawings without doing any creative activity.

FIG. 1 is a schematic cross-sectional diagram of a display panel according to one embodiment of the present application.

FIG. 2 is a schematic diagram of a first arrangement of a touch function layer and a cathode layer according to one embodiment of the present application.

FIG. 3 is a schematic diagram of a second arrangement of a touch function layer and a cathode layer according to one embodiment of the present application.

FIG. 4 is a schematic diagram of a third arrangement of a touch function layer and a cathode layer according to one embodiment of the present application.

FIG. 5 is a schematic diagram of a fourth arrangement of a touch function layer and a cathode layer according to one embodiment of the present application.

FIG. 6 is a schematic diagram of an arrangement of a display panel according to one embodiment of the present application.

FIG. 7 is a schematic diagram showing a formation of a cathode layer according to one embodiment of the present application.

### DETAILED DESCRIPTION OF PREFERRED EMBODIMENTS

The following description of the embodiments is provided to illustrate the specific embodiments of the invention. Directional terminologies mentioned in the application, such as “above”, “under”, “front”, “back”, “left”, “right”, “inside”, “outside”, “side”, etc., are only refer to the directions of the accompanying drawings. Therefore, the directional terminology used is for illustrating and understanding the application and is not intended to limit the application. In the figures, structurally similar components are denoted by the same reference numerals.

The embodiment of the application is to solve the problem that a touch panel structure of the current display panel can only be implemented by the on-cell method.

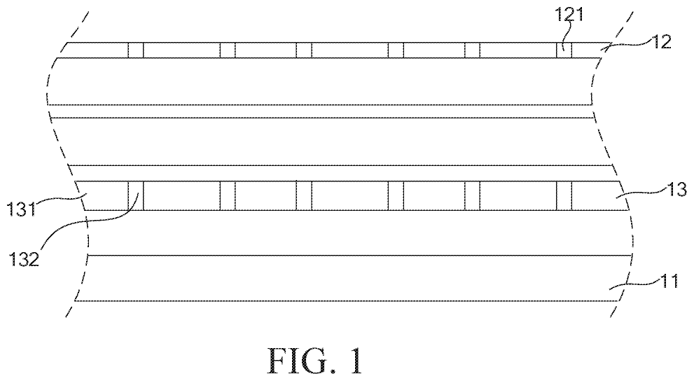

As shown in FIG. 1, in one embodiment, the display panel 1 provided by the present application includes: a substrate 11; a cathode layer 12 formed by a low-temperature process, disposed on the substrate 11, wherein a first gap 121 is disposed on the cathode layer 12; and a touch function layer 13, wherein at least one touch function layer 13 is not disposed on a side of the cathode layer 12 away from the substrate 11, the touch function layer 13 is provided with a touch component, 131 and an adjacent touch component 131 positioned in the same touch function layer 13 is provided with a second gap 132; and wherein the second gap 132 and the first gap 121 satisfy a preset condition, the preset condition makes the touch component 131 to form a touch function unit.

The present application provides a new display panel and a display device. The display panel includes: a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

In this structure, based on the first gap formed on the cathode layer, after a finger touches screen, the generated lines of force are not shielded by the cathode layer and can penetrate a structure under the cathode. In this way, at least part of the touch function layer can be not disposed on the cathode layer of the uppermost layer of the OLED away from the back panel, thereby solving the technical problem that the current display panel can only adopt the on-cell method. In addition, the cathode layer is formed by low-temperature process, which avoids damage to the luminescent material.

The touch component includes an optical touch unit and a capacitive touch unit. The capacitive touch unit includes a mutual capacitive touch function unit and a self-capacitive touch function unit. The application can be applied to all touch component implementations.

In one embodiment, the optical touch unit includes a light-emitting unit and a light-receiving unit (a second gap is formed therebetween). The first gap of the cathode layer is disposed at least at an optical transmission path, the optical transmission path includes an emitting path and a receiving path. In this way, the light can pass through the cathode layer to reach a surface of the terminal device, thereby implementing the touch control function.

In one embodiment, the touch component of the same touch function layer includes a driving electrode and a sensing electrode, and the second gap is formed between the adjacent driving electrode and the sensing electrode. An inductance line between the driving electrode and the sensing electrode passes through the first gap to form a mutual capacitive touch function unit.

In one embodiment, the touch function layer is disposed between the cathode layer and the substrate. A first projection of the first gap on the substrate covers a second projection of the second gap on the substrate along a projection direction perpendicular to the substrate.

In one embodiment, the touch function layer is disposed between the cathode layer and the substrate. A first projection of the first gap on the substrate coincides with a second projection of the second gap on the substrate along a projection direction perpendicular to the substrate.

In one embodiment, the touch function layer is disposed in the same layer as the signal wiring layer of the display panel.

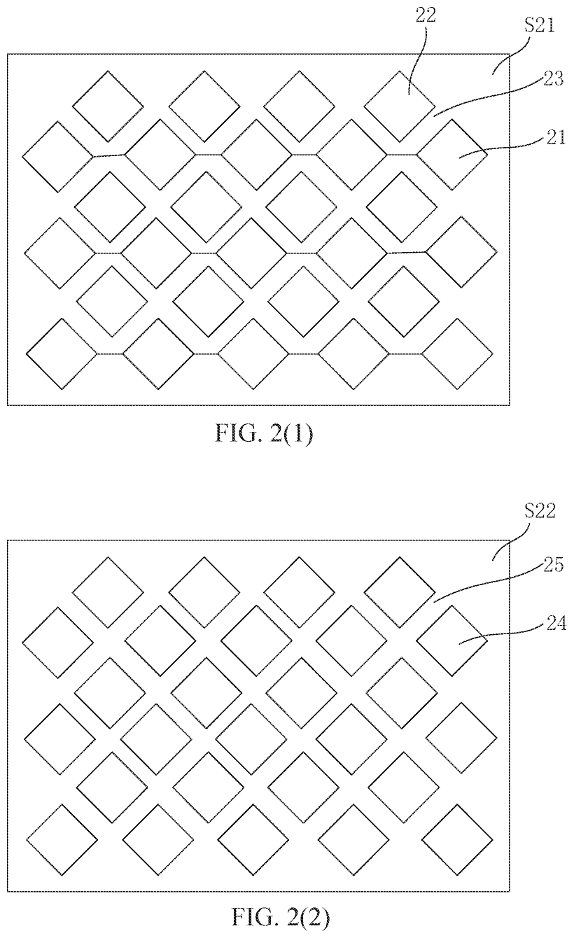

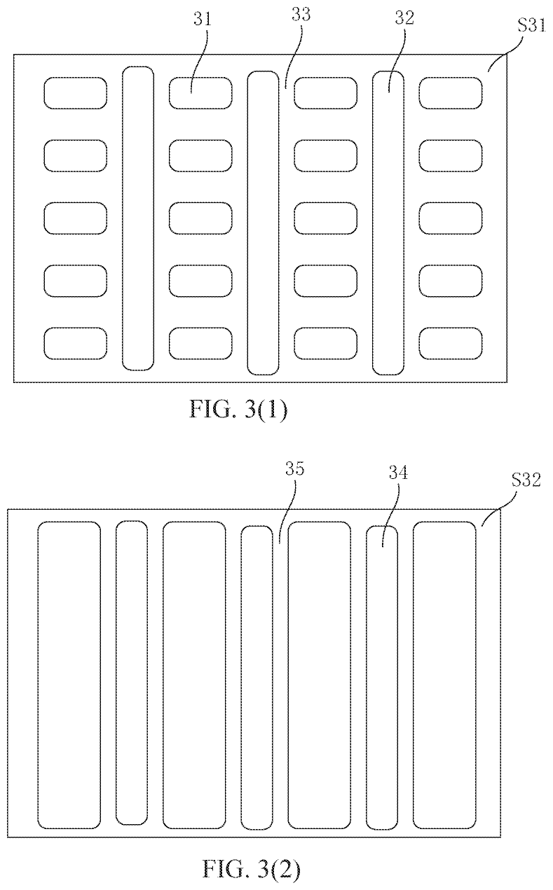

In one embodiment of the present application, a current LTPS array layer, a corresponding signal wiring layer such as Vi and VDD can be used to prepare a sensor of the driving electrode TX and the sensing electrode RX. At the same time, the current pixel driving signal is used to provide a driving signal to the sensor during a working period of the touch component, and a cathode layer located directly above the adjacent regions of TX and RX is removed. As shown in FIG. 2 and FIG. 3, a diamond shape and a rectangle shape are taken as an example, and other shapes such as a triangle are also included in the present application.

As shown in FIG. 2 (1), after signal wiring layer S21 is patterned, a diamond-shaped sensor is formed, and driving electrodes 21 of the same column are directly electrically connected by a wire, and sensing electrodes 22 of the same row are electrically connected by a bridge. A second gap 23 is formed between the adjacent driving electrode 21 and the sensing electrode 22. In one embodiment, a boundary of the region adjacent to the driving electrode 21 and the sensing electrode 22 may not be a complete linear gap. For example, it may be a complex boundary disposed to be engaged with each other so that a better touch control effect can be achieved.

As shown in FIG. 2 (2), after cathode layer S22 is patterned, a plurality of rhombic structures 24 are formed, and a first gap 25 is formed between the adjacent rhombic structures 24, and a second gap 23 has the same shape as the first gap 25.

As shown in FIG. 3 (1), after signal wiring layer S31 is patterned, rectangular sensors are formed, and driving electrodes 31 of the same column are electrically connected by means of bridges or via holes. A sensing electrode 32 is directly connected to a driving chip, and a second gap 33 is formed between the adjacent driving electrode 31 and the sensing electrode 32. In one embodiment, a boundary of the region adjacent to the driving electrode 31 and the sensing electrode 32 may not be a complete linear gap. For example, it may be a complex boundary disposed to be engaged with each other so that a better touch control effect can be achieved.

As shown in FIG. 3 (2), after cathode layer S32 is patterned, a plurality of rectangular structures 34 are formed, and a first gap 35 is formed between the adjacent rectangular structures 34, and the second gap 33 has the same shape as the first gap 35.

In one embodiment, the touch components of the same touch function layer include a driving electrode and a sensing electrode, and the second gap is formed between the adjacent driving electrode and the sensing electrode. The touch function layer is disposed in the same layer as the cathode layer, and the first gap and the second gap are coincident.

In this embodiment, touch electrodes Tx and Rx wirings are formed by cathode. Adopting time-division multiplexing in the display stage and the touch control stage, the Tx or Rx connection is disposed above or below the cathode, and a transparent insulating layer is provided between the wirings and the cathode layer.

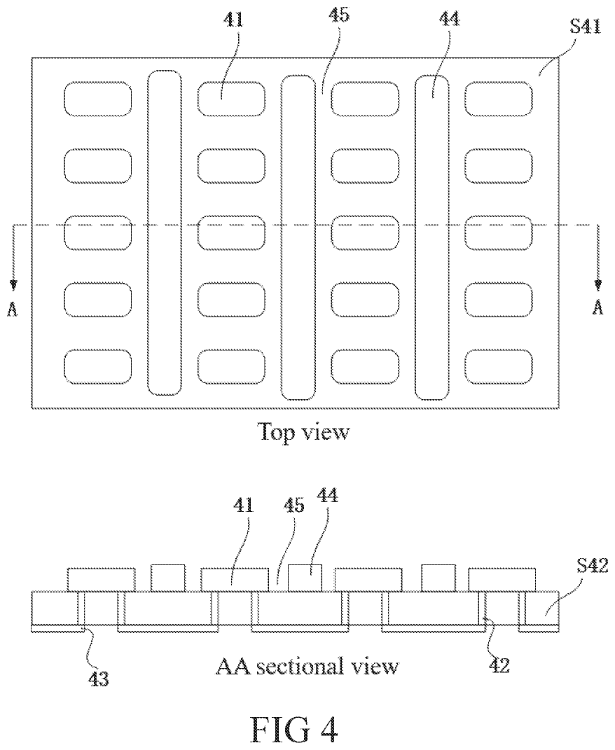

As shown in FIG. 4, cathode layer S41 is patterned to form a rectangular sensor. Driving electrodes 41 of the same column are electrically connected by a combination of a via hole 42 and a wiring 43. The wiring 43 is disposed on a side of the cathode layer S41 facing the back panel. An insulating layer S42 is disposed between the wiring 43 and the cathode layer S41, and a sensing electrode 44 is directly connected to a driving chip. A second gap 45, that is, a first gap is formed between the adjacent driving electrode 41 and the sensing electrode 44. In one embodiment, a boundary of the region adjacent to the driving electrode and the sensing electrode may not be a complete linear gap. For example, it may be a complex boundary disposed to be engaged with each other so that a better touch control effect can be achieved.

In one embodiment, a wiring 43 is disposed on a side of the cathode layer away from the back panel, and an insulating layer is disposed between the wiring 43 and the cathode layer.

In one embodiment, after cathode wiring layer is patterned, a diamond-shaped sensor is formed, and the driving electrodes of the same column are directly electrically connected by a wire, and sensing electrodes of the same row are electrically connected by a bridge. A second gap, that is, a first gap is formed between the adjacent driving electrode and the sensing electrode. In one embodiment, a boundary of the region adjacent to the driving electrode and the sensing electrode may not be a complete linear gap. For example, it may be a complex boundary disposed to be engaged with each other so that a better touch control effect can be achieved.

In one embodiment, the touch components of the same touch function layer include a touch electrode, and the second gap is formed between adjacent touch electrodes. An inductance line between the touch electrodes passes through the first gap to form a self-capacitive touch function unit.

In one embodiment, the touch function layer is disposed between the cathode layer and the substrate. A first projection of the first gap on the substrate covers a second projection of the second gap on the substrate along a projection direction perpendicular to the substrate.

In one embodiment, the touch function layer is disposed between the cathode layer and the substrate. A first projection of the first gap on the substrate coincides with a second projection of the second gap on the substrate along a projection direction perpendicular to the substrate.

In one embodiment, the touch function layer is disposed in the same layer as the signal wiring layer of the display panel.

In one embodiment, the touch components of the same touch function layer include a touch electrode, and the second gap is formed between the adjacent touch electrode. The touch function layer is disposed in the same layer as the cathode layer, and the first gap and the second gap are coincident.

For the self-capacitive touch function unit, an arrangement manner of each touch electrode (generally a driving electrode) can be referred to the mutual-capacitive touch function unit, and will not be described here.

In one embodiment, the touch function layer includes a first touch function layer and a second touch function layer. The first touch function layer forms a first touch electrode, and the second touch function forms a sensing electrode. The first touch function layer is disposed in the same layer as the cathode layer, the adjacent first touch electrodes form the first gap, and the adjacent second touch electrodes form the second gap. A first projection of the first gap on the substrate intersects a second projection of the second gap on the substrate along a projection direction perpendicular to the substrate. An inductance line between the first touch electrode and the second touch electrode passes through the first gap to form a mutual capacitive touch function unit.

In one embodiment, a first projection of the first gap on the substrate is perpendicular to a second projection of the second gap on the substrate.

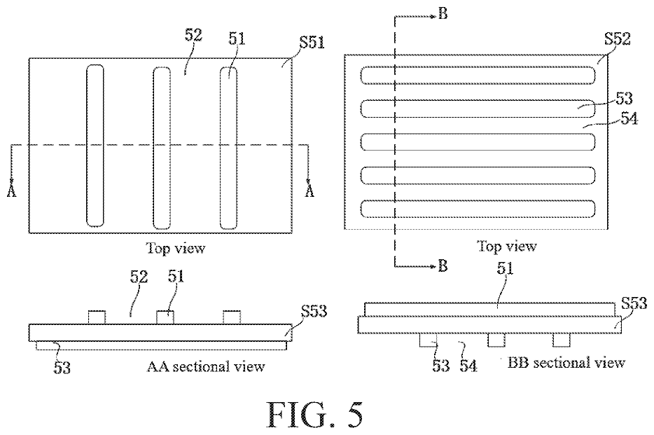

As shown in FIG. 5, in one embodiment, the present application forms a first touch electrode 51 (which is a wire of Tx or Rx) by using a cathode layer S51. The electrodes 51 of the same column/row are connected to each other through a via hole, and a first gap 52 is formed between the first touch electrodes 51. The other touch function layer S52 forms a second touch electrode 53 (Rx or Tx electrode), and a second gap 54 is formed between the second touch electrodes 53. The second gap 54 is perpendicular to the first gap 52. The touch function layer S52 is disposed in the direction of the cathode layer S51 facing the back panel, and the touch function layer S52 and the cathode layer S51 are directly provided with the insulating layer S53. In the display and touch stages, display and touch control are realized by means of time-division multiplexing.

In one embodiment, the adjacent first touch electrodes 51 are directly connected by wires.

In one embodiment, the touch function layer S52 is disposed in a direction away from the back panel of the cathode layer S51, and the touch function layer S52 and the cathode layer S51 are directly provided with an insulating layer.

In order to achieve a low-temperature process to form a cathode layer and to avoid damage to the luminescent material layer, the present application also provides various implementations.

The current support retaining wall PS column is a cylindrical column with a cross-section of a trapezoidal shape and a height of 1.5 um, which serves as a support for the evaporation masks, and it is covered with the cathode layer of its entire surface. A height of the PS column is increased in this application, so that a cathode material deposited according to an original process will not completely cover an entire film layer, and will expose a gap formed by the separation of the cathode layer due to the higher PS column. Thus, a patterning of the cathode can be realized.

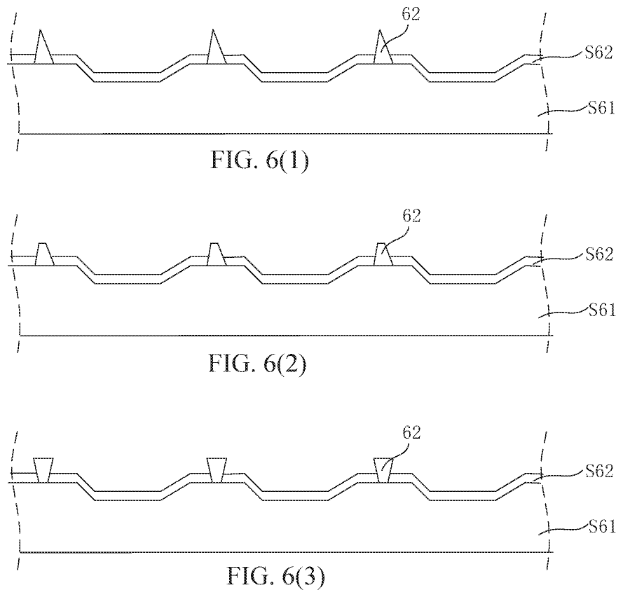

In one embodiment, as shown in FIG. 6, the display panel includes a pixel defining layer S61, and a support retaining wall 62 disposed on the pixel defining layer S61, and a height of the support retaining wall 62 is greater than a thickness of the cathode layer S62, the cathode layer S62 is divided to form the first gap.

In one embodiment, as shown in FIG. 6 (1), the support retaining wall 62 has a cross-section of triangular.

In one embodiment, the support retaining wall 62 has a cross-section of an isosceles triangle.

In this embodiment, the PS column is formed into a shape having a higher height and having a cross-section of an isosceles triangle, separating the cathode material to realize a patterning of the cathode.

In one embodiment, as shown in FIG. 6 (2), the support retaining wall 62 has a cross-section of trapezoidal.

In one embodiment, the support retaining wall 62 has a cross-section of isosceles trapezoidal.

In this embodiment, the PS column is formed into a cylindrical support column having a higher height and a cross-section of isosceles trapezoid. Due to the higher height, the cathode material can be separated and a patterning of the cathode can be realized without changing the cathode deposition process.

In one embodiment, as shown in FIG. 6 (3), the support retaining wall 62 has a cross-section of inverted trapezoidal.

In one embodiment, the support retaining wall 62 has a cross-section of inverted isosceles trapezoidal shape. In this embodiment, the PS column is formed into a cylindrical support column having a higher height and a cross-section of inverted isosceles trapezoidal shape. Due to its higher height, the shape of inverted isosceles trapezoidal make it more able to separate the cathode material, and the best cathode patterning effect is realized. Cathode patterning is achieved by the adjacent same type of sensor pads (Tx/Rx of different rows or columns) and adjacent different types of sensor pads (e.g., between adjacent Tx and Rx), separated by the PS pillars.

The current method for making a cathode layer is to use Common Metal Mask (CMM) to deposit an entire surface of the cathode layer on top of the luminescent material EL layer. RGB pixel materials of an OLED device is made by using Fine Metal Mask (FMM). Thus, when patterning a cathode layer, the present application directly realizes its patterning by using the FMM and can ensure an accuracy satisfies a high PPI design of display region.

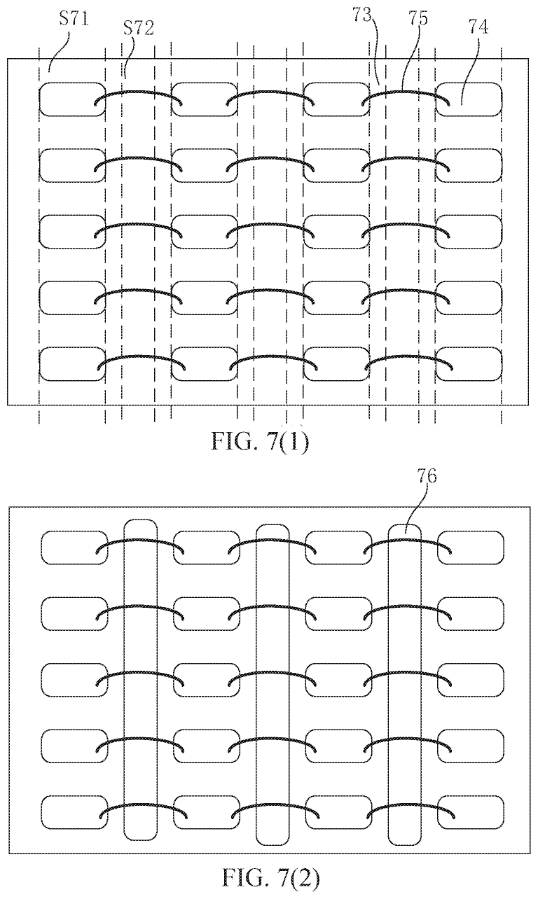

As shown in FIG. 7 (1), first, a first layer FMM is selectively deposited to form a first region S71 as a driving electrode Tx electrode 74, and connects it to the Tx column/row connection 75.

As shown in FIG. 7 (2), then a second layer FMM is selectively deposited to form a second region S72 as an Rx electrode 76, which is isolated from Tx and Tx line.

Finally, a layer of TFE is deposited to encapsulate the entire cathode layer, the entire process does not require a photo and etching processes and can prevent the OLED light-emitting devices below from damaging by the photo and the etching processes.

In one embodiment, the touch function layer is the same layer as the cathode layer, the cathode layer of the first region forms a first touch electrode, and the cathode layer of the second region forms a second touch electrode.

In one embodiment, the first touch electrode is a driving electrode, and the second touch electrode is a sensing electrode; or the first touch electrode is a sensing electrode, and the second touch electrode is a driving electrode.

In one embodiment, the present application adopts a low-temperature material, a low-temperature process, a photoresist, a low-temperature PR glue, and a conventional etching process. The passivation layer and the protective layer are added in the process to avoid etching too much and damaging the OLED light-emitting device, thereby realizing the cathode layer patterning. In this embodiment, the display panel includes a passivation layer and a protective layer sequentially disposed on the cathode layer. The first gap is formed by etching the passivation layer, the protection layer, and the cathode layer in one process.

In one embodiment, the present application coating a patterned stripping adhesive prior to depositing an entire surface of the cathode layer, and removing the stripping adhesive after depositing the cathode layer to realize a patterning of the cathode layer. In this embodiment, the first gap is a stripping layer disposed under the cathode layer and is formed by stripping.

Meanwhile, in one embodiment, one embodiment of the present application further provides a display device, the display device includes a display panel, and the display panel includes a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

In one embodiment, in the display device of the present application, the display panel includes a pixel defining layer, and the pixel defining layer is provided with a support retaining wall thereon; wherein a height of the support retaining wall is greater than a thickness of the cathode layer; and wherein the cathode layer is divided to form the first gap.

In one embodiment, in the display device of the present application, the support retaining wall has a cross-section of triangular.

In one embodiment, in the display device of the present application, the support retaining wall has a cross-section of trapezoidal.

In one embodiment, in the display device of the present application, the support retaining wall has a cross-section of inverted trapezoidal.

In one embodiment, in the display device of the present application, the cathode layer includes a first region and a second region, and the first gap is disposed between the first region and the second region, and wherein the cathode layer of the first region and the second region is formed by a plurality of processes.

In one embodiment, in the display device of the present application, the touch function layer is the same layer as the cathode layer, and wherein the cathode layer of the first region forms a first touch electrode, and the cathode layer of the second region forms a second touch electrode.

In one embodiment, in the display device of the present application, the first touch electrode is a driving electrode, and the second touch electrode is a sensing electrode; or else the first touch electrode is a sensing electrode, and the second touch electrode is a driving electrode.

In one embodiment, in the display device of the present application, the display panel includes a passivation layer and a protective layer sequentially disposed on the cathode layer, and the first gap is formed by etching the passivation layer, the protection layer, and the cathode layer in one process.

In one embodiment, in the display device of the present application, the first gap is formed by stripping a stripping layer disposed under the cathode layer.

According to the above embodiment, it can be known that the present application provides a new display panel and a display device. The display panel includes a substrate; a cathode layer formed by a low-temperature process, disposed on the substrate, wherein a first gap is disposed on the cathode layer; and a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

In this structure, based on the first gap formed on the cathode layer, after a finger touches screen, the generated lines of force are not shielded by the cathode layer and can penetrate a structure under the cathode. In this way, at least part of the touch function layer can be not disposed on the cathode layer of the uppermost layer of the OLED away from the back panel, thereby solving the technical problem that the current display panel can only adopt on-cell method. In addition, the cathode layer is formed by a low-temperature process, which avoids damage to the luminescent material.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. A display panel, comprising:
a substrate;
a cathode layer formed by a low-temperature process, disposed on the substrate, wherein a first gap is disposed on the cathode layer; and
a touch function layer, wherein at least one touch function layer is not disposed on a side of the cathode layer away from the substrate, the touch function layer is provided with a touch component, and a second gap is formed between the touch component and an adjacent touch component positioned in a same touch function layer; and wherein the second gap and the first gap satisfy a preset condition, the preset condition makes the touch component to form a touch function unit.

2. The display panel according to claim 1, wherein the display panel comprises a pixel defining layer, the pixel defining layer is provided with a support retaining wall thereon; wherein a height of the supporting retaining wall is greater than a thickness of the cathode layer; and wherein the cathode layer is divided to form the first gap.

3. The display panel according to claim 2, wherein the support retaining wall has a triangular cross-section.

4. The display panel according to claim 2, wherein the support retaining wall has a trapezoidal cross-section.

5. The display panel according to claim 2, wherein the support retaining wall has an inverted trapezoidal cross-section.

6. The display panel according to claim 1, wherein the cathode layer comprises a first region and a second region, and the first gap is disposed between the first region and the second region, and wherein the cathode layer of the first region and the second region is formed by a plurality of processes.

7. The display panel according to claim 6, wherein the touch function layer is a same layer as the cathode layer, and wherein the cathode layer of the first region forms a first touch electrode, and the cathode layer of the second region forms a second touch electrode.

8. The display panel of claim 7, wherein the first touch electrode is a driving electrode, and the second touch electrode is a sensing electrode; or the first touch electrode is a sensing electrode, and the second touch electrode is a driving electrode.

9. The display panel according to claim 1, wherein the display panel comprises a passivation layer and a protective layer sequentially disposed on the cathode layer, and the first gap is formed by etching the passivation layer, the protection layer, and the cathode layer in one process.

10. The display panel according to claim 1, wherein the first gap is formed by stripping a stripping layer disposed under the cathode layer.

11. A display device, comprising a display panel, wherein the display panel comprises:
a substrate;
a cathode layer formed by a low-temperature process, disposed on the substrate, wherein a first gap is disposed on the cathode layer; and
a touch function layer, wherein at least one touch function layer is not disposed on a side of the cathode layer away from the substrate, the touch function layer is provided with a touch component, and a second gap is formed between the touch component and an adjacent touch component positioned in the same touch function layer; and wherein the second gap and the first gap satisfy a preset condition, the preset condition makes the touch component to form a touch function unit.

12. The display device according to claim 11, wherein the display panel comprises a pixel defining layer, and the pixel defining layer is provided with a support retaining wall thereon; wherein a height of the supporting retaining wall is greater than a thickness of the cathode layer; and wherein the cathode layer is divided to form the first gap.

13. The display device according to claim 12, wherein the support retaining wall has a triangular cross-section.

14. The display device according to claim 12, wherein the support retaining wall has a trapezoidal cross-section.

15. The display device according to claim 12, wherein the support retaining wall has an inverted trapezoidal cross-section.

16. The display device according to claim 11, wherein the cathode layer comprises a first region and a second region, and the first gap is disposed between the first region and the second region, and wherein the cathode layer of the first region and the second region is formed by a plurality of processes.

17. The display device according to claim 16, wherein the touch function layer is the same layer as the cathode layer, and wherein the cathode layer of the first region forms a first touch electrode, and the cathode layer of the second region forms a second touch electrode.

18. The display device according to claim 17, wherein the first touch electrode is a driving electrode, and the second touch electrode is a sensing electrode; or the first touch electrode is a sensing electrode, and the second touch electrode is a driving electrode.

19. The display device according to claim 11, wherein the display panel comprises a passivation layer and a protective layer disposed on the cathode layer, and the first gap is formed by etching the passivation layer, the protection layer, and the cathode layer in one process.

20. The display device according to claim 11, wherein the first gap is formed by stripping a stripping layer disposed under the cathode layer.
